(19) United States
(12) Patent Application Publication
(10) Pub. No.: US 2013/0206202 A1
(43) Pub. Date: Aug. 15, 2013

(54) SOLAR CELL

(71) Applicants: Yeon il Lee, Seoul (KR); Dong Kyun Kim, Suwon-si (KR); Yun Gi Kim, Yongin-si (KR); Chul Ki Kim, Samcheok-si (KR); Eun Cheol Do, Daegu (KR); Young Moon Choi, Seoul (KR)

(72) Inventors: Yeon il Lee, Seoul (KR); Dong Kyun Kim, Suwon-si (KR); Yun Gi Kim, Yongin-si (KR); Chul Ki Kim, Samcheok-si (KR); Eun Cheol Do, Daegu (KR); Young Moon Choi, Seoul (KR)

(73) Assignee: SAMSUNG ELECTRONICS CO., LTD., Suwon-si (KR)

(21) Appl. No.: 13/484,902

(22) Filed: May 31, 2012

(30) Foreign Application Priority Data
Feb. 13, 2012 (KR) 1020120014489

(51) Int. Cl. H01L 31/0216; H01L 31/042; H01L 31/0232

(52) U.S. Cl. 136/244; 136/256

(57) ABSTRACT

According to example embodiments, a solar cell includes a photoelectric member on a passivation member. The photoelectric member is configured to convert incident light into current. The passivation member includes protection material for protecting the-photoelectric member and wavelength conversion material configured to convert light that passes through the photoelectric member into different wavelength.

### RELATED APPLICATIONS

This application claims priority under 35 U.S.C. §119 to Korean Patent Application No. 10-2012-0014489 filed in the Korean Intellectual Property Office on Feb. 13, 2012, the entire contents of which are incorporated herein by reference.

### BACKGROUND

1. Field

Example embodiments relate to a solar cell.

2. Description of the Related Art

Solar light is gaining attention as a substitute energy source for fossil fuels. Solar cells can convert solar light into electricity and may be classified into crystalline solar cells, compound thin film solar cells, organic solar cells, etc.

Crystalline solar cells may contain single crystalline silicon. For crystalline solar cells, the current photoelectric conversion ratio may be about 25%. The theoretical limit of a silicon solar cell is about 30%, due to the photoelectric characteristics of silicon. A silicon photoelectric layer may have a conversion ratio that is greater than or equal to about 90% for short wavelengths, for example, from about 300 nm to about 1,100 nm. However, light having a long wavelength, for example, greater than about 1,100 nm, may not contribute to power generation.

### SUMMARY

Example embodiments relate to a solar cell.

According to example embodiments, a solar cell includes a photoelectric member on a passivation member. The photoelectric member is configured to convert light into current. The passivation member includes protection material for protecting the photoelectric member and wavelength conversion material configured to convert light that passes through the photoelectric member into a different wavelength.

The wavelength conversion material may include at least one of a rare earth ion, a transition metal ion, and a quantum dot.

The protection material may include at least one of silicon oxide, silicon nitride, and aluminum oxide.

The photoelectric member may include single crystalline silicon, and the wavelength conversion material may be configured to converts light having a wavelength of about 1,100 nm to about 1,700 nm into light having a wavelength of about 550 nm to about 850 nm.

The passivation member may include a first protection layer including the protection material, and the wavelength conversion material may be in the first protection layer.

The wavelength conversion material may include at least one of a rare earth ion and a transition metal ion. The at least one of the rare earth ion and the transition metal ion may be introduced into the first protection layer by ion implantation.

The protection material may include at least one of silicon oxide and silicon nitride, and the wavelength conversion material may include a quantum dot. The quantum dot may be a Si nanocrystal.

The wavelength conversion material may include a quantum dot and at least one of a rare earth ion and a transition metal ion. The quantum dot may be a Si nanocrystal. The rare earth ion and a transition metal ion may be introduced into the first protection layer by ion implantation.

The passivation member may further include a micro-lens array on the first protection layer.

The wavelength conversion material in the first protection layer may be near a first surface of the first protection layer. The first surface of the first protection layer may be closer to the micro-lens array than a second surface of the first protection layer opposite the first surface.

The passivation member may further include a second protection layer on the micro-lens array.

The passivation member may include a first protection layer including the protection material and a wavelength conversion layer that is under the first protection layer. The wavelength conversion layer includes the wavelength conversion material.

The passivation member may further include a second protection layer under the wavelength conversion material. The second protection layer may include the protection material.

The solar cell may further include a reflection member under the wavelength conversion material.

The protection material may surround the wavelength conversion material such that the wavelength conversion material is spaced apart from the reflection member and not in contact with the reflection member.

The photoelectric member may include a junction of an active layer and an emitter that have opposite conductivities.

The emitter may be further from the passivation member than the active layer, and the solar cell may further include a second protection layer configured to protect a surface of the emitter.

The solar cell may further include a first electrode connected to the active layer; and a second electrode connected to the emitter, wherein the first and second electrodes are on one side or opposite sides of the solar cell.

The photoelectric member may include at least two units separated by an insulating layer.

The passivation member may further include a micro-lens array between the photoelectric member and the wavelength conversion layer.

The passivation member may further include a second protection layer on the micro-lens array.

The passivation member may further include a second protection layer under the wavelength conversion material. The first and second protection layers may include different materials.

The photoelectric member may include a p-i-n junction.

A transparent conductive oxide pattern may surround the passivation member. The transparent conductive oxide pattern may connect the photoelectric member to the reflecting member.

The photoelectric member may include at least one of an elemental semiconductor, a compound semiconductor, and an organic semiconductor.

### BRIEF DESCRIPTION OF THE DRAWINGS

The foregoing and other features and advantages of example embodiments will be apparent from the more particular description of non-limiting embodiments, as illustrated in the accompanying drawings in which like reference characters refer to the same parts throughout the different views. The drawings are not necessarily to scale, emphasis instead being placed upon illustrating the principles of example embodiments. In the drawings:

FIG. 1 is a schematic diagram of a solar cell according to example embodiments.

FIGS. 2 to 6, 7A, and 7B are schematic sectional views of passivation members according to example embodiments.

FIG. 8 is a graph showing light spectrums for various wavelength conversion ratios.

FIG. 9 is a graph showing current-voltage (I-V) curves for various wavelength conversion ratios.

FIGS. 10 to 20, and 21(a) to 21(b) are schematic sectional views of solar cells according to example embodiments.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments to those of ordinary skill in the art. In the drawings, the thicknesses of layers and regions are exaggerated for clarity. Like reference numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

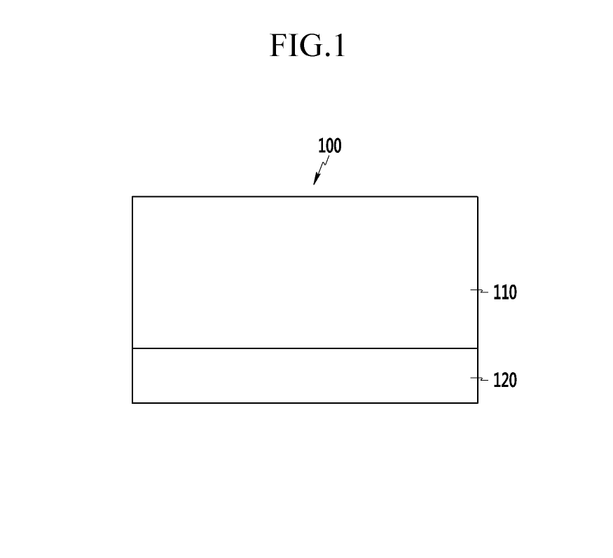

A solar cell according to example embodiments is described in detail with reference to FIG. 1.

FIG. 1 is a schematic diagram of a solar cell according to example embodiments.

Referring to FIG. 1, a solar cell 100 according to example embodiments includes a photoelectric member 110 and a passivation member 120 under the photoelectric member 110.

The photoelectric member 110 may absorb incident light and produce holes and electrons to generate current. The photoelectric member 110 may include, for example, an elemental semiconductor, a compound semiconductor, and an organic semiconductor, and may have various structures.

The photoelectric member 110 may absorb light and convert the absorbed light into current. The range of light absorbed and converted into current by the photoelectric member 110 depends on the material(s) of the photoelectric member 110. For example, a photoelectric member 110 containing single crystalline silicon may absorb light having a short wavelength range of about 300 nm to about 1,100 nm and convert the absorbed short wavelength light into current.

The passivation member 120 may protect the photoelectric member 110, and may convert light having a wavelength range that may not be absorbed by the photoelectric member 110 into light having another wavelength range that may be absorbed by the photoelectric member 110. For example, when the photoelectric member 110 uses short-wavelength light in power generation but rarely use long-wavelength light as in the above example, the passivation member 120 may convert the long-wavelength light into the short-wavelength light. However, example embodiments are not limited thereto

The passivation member 120 may include a material or a structure that can conduct wavelength conversion (referred to as “wavelength conversion material” hereinafter), for example, at least one of rare earth ions, transition metal ions, and nanocrystals such as quantum dots. The wavelength conversion materials may convert, for example, light with a wavelength of about 1,100 nm to about 1,700 nm into light with a wavelength of about 550 nm to about 850 nm, but example embodiments are not limited thereto. The wavelength conversion materials may emit a high-energy photon after absorbing two low-energy photons, thereby converting a long-wavelength light into a short-wavelength light.

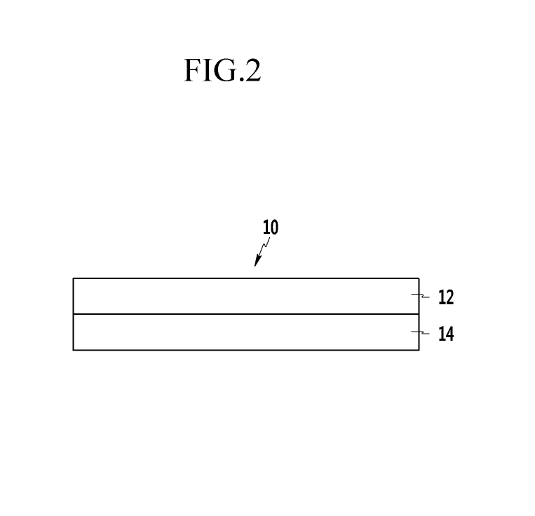

Examples of rare earth ions include Er³⁺, Tb³⁺, Tm³⁺, and Yb³⁺, but example embodiments are not limited thereto. Examples of transition metal ions include Zn, Pb, Ti, and Cd⁺, but example embodiments are not limited thereto. The passivation member 120 may further include at least one material for protecting the photoelectric member 110 (referred to as “protection material” hereinafter). The protection material may include a dielectric material, for example, at least one of silicon oxide (SiOₓ), silicon nitride (SiNₓ), and aluminum oxide (Al₂O₃), but example embodiments are not limited thereto. The protection material and wavelength conversion material in the passivation member 120 may be implemented as separate layers or may be integrated in a single layer, which is described in detail with reference to FIGS. 2 to 6, 7A and 7B.

FIGS. 2 to 6, 7A and 7B are schematic sectional views of passivation members according to example embodiments.

Referring to FIG. 2, a passivation member 10 according to example embodiments includes a protection layer 12 including protection material and a wavelength conversion layer 14 including wavelength conversion material and disposed under the protection layer 12. The wavelength conversion layer 14 may be formed by sputtering a wavelength conversion material, or by coating a solution including a wavelength conversion material and then by removing solvent by evaporation, etc.

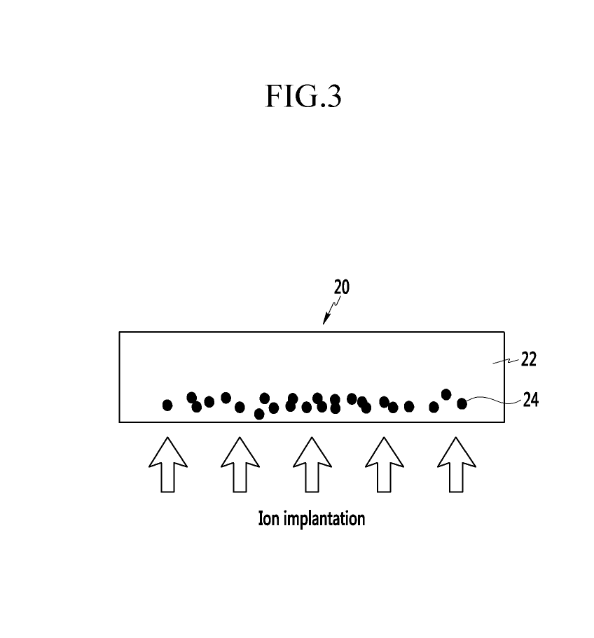

Referring to FIG. 3, a passivation member 20 according to example embodiments includes a protection layer 22 including protection material and ion-type wavelength conversion materials 24, for example, rare earth ions or transition metal ions are doped in the protection layer 22. The doped ion-type wavelength conversion materials 24 may include a single type of ions or a plural type of ions, or may include both a rare earth ion and a transition metal ion. This structure may be formed by implanting the ion-type wavelength conversion materials 24 into the protection layer 22 after forming the protection layer 22.

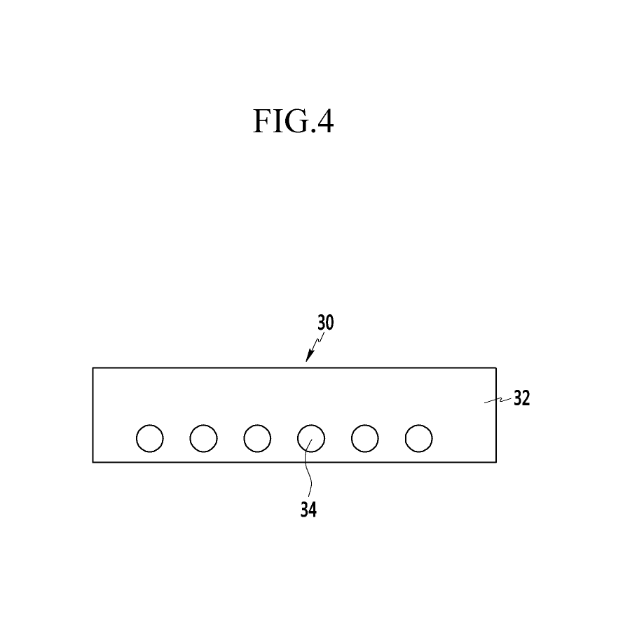

Referring to FIG. 4, a passivation member 30 according to example embodiments includes a protection layer 32 including protection material, and quantum dots 34 are formed in the protection layer 32. The quantum dots 34 may be formed by various methods. For example, when forming the protection layer 32 by depositing SiOₓ or SiNₓ using chemical vapor deposition (CVD), etc., if the concentration of silicon is high, some silicon atoms in the protection layer 32 may not combine with oxygen or nitrogen. Thereafter, when the protection layer 32 is annealed, silicon atoms that do not combine with oxygen or nitrogen may form nanocrystals in the protection layer 32 to form the quantum dots 34.

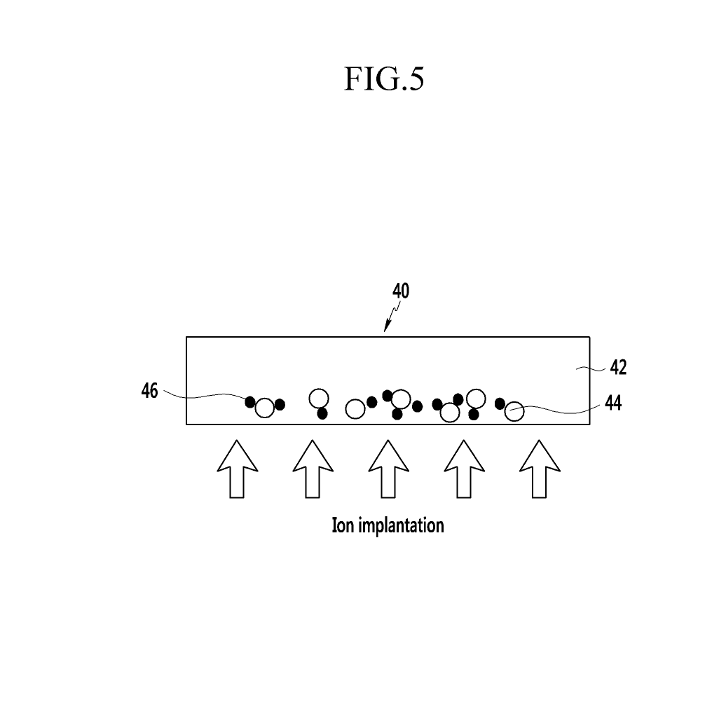

Referring to FIG. 5, a passivation member 40 according to example embodiments includes a protection layer 42 including protection material 42, and both quantum dots 44 and ion-type wavelength conversion materials 46 are formed in the protection layer 42. The ion-type wavelength conversion materials 46 may include a single type of ions or a plural type of ions, or may include both a rare earth ion and a transition metal ion. The passivation member 40 may be formed by forming the quantum dots 44 in the protection layer 42 by the method described above with reference to FIG. 4 and thereafter, by implanting the ion-type wavelength conversion materials 46 into the protection layer 42 by the method described above with reference to FIG. 3. The passivation member 40 including heterogeneous wavelength conversion materials 44 and 46 may have increased wavelength conversion efficiency.

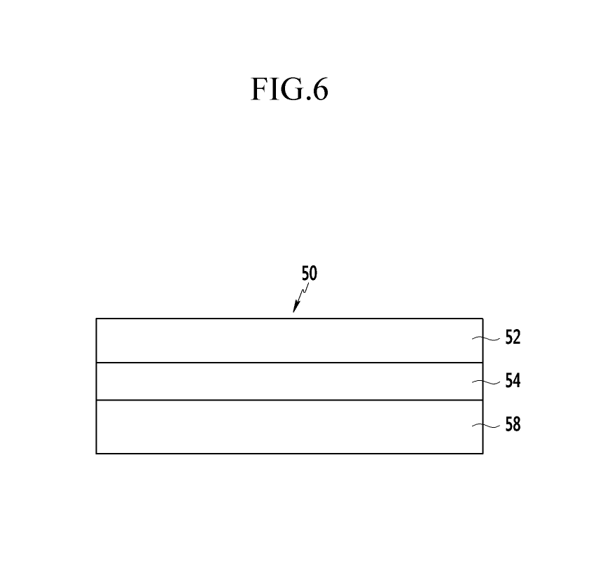

Referring to FIG. 6, a passivation member 50 according to example embodiments include two protection layers, for example, an upper protection layer 52 and a lower protection layer 58 that include protection material(s). The passivation member 50 further includes a wavelength conversion layer 54 including a wavelength conversion material and disposed between the two protection layers 52 and 58. The additional protection layer, that is, the lower protection layer 58 may reduce (and/or prevent) the decrease of efficiency of the solar cell caused by the deterioration of the wavelength conversion layer 54 that may occur when the wavelength conversion layer 54 is in direct contact with another metal layer. The upper protection layer 52 and the lower protection layer 58 may include the same or different materials for the protection materials. For example, both the upper 52 and lower protection layer 58 may include one dielectric material including at least one of silicon oxide (SiOₓ), silicon nitride (SiNₓ), and aluminum oxide (Al₂O₃). Alternatively, the upper protection layer 52 may include one of silicon oxide (SiOₓ), silicon nitride (SiNₓ), and aluminum oxide (Al_{2O}₃) and the lower protection layer may include another one of silicon oxide (SiOₓ), silicon nitride (SiNₓ), and aluminum oxide (Al₂O₃). However, example embodiments are not limited thereto.

The passivation members 20, 30 and 40 shown in FIGS. 3 to 5 may further include an additional protection layer (not shown) on a surface (e.g., a lower surface) close to the wavelength conversion materials 24, 34, 44 and 46.

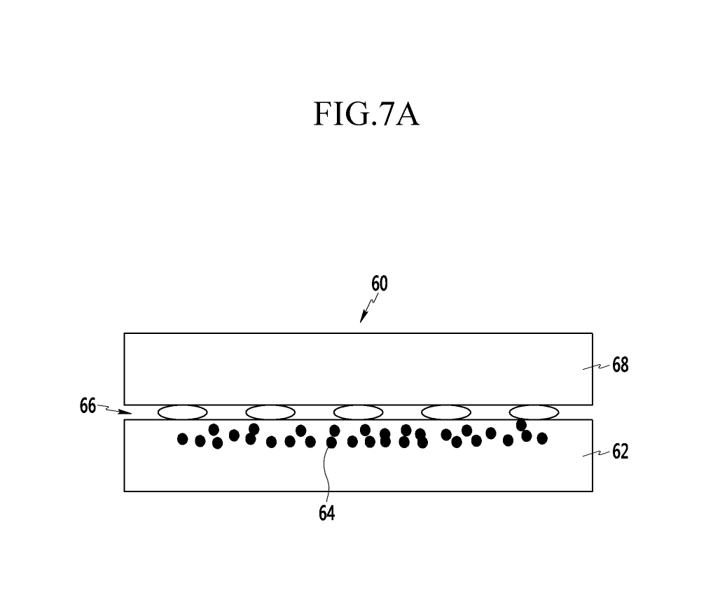

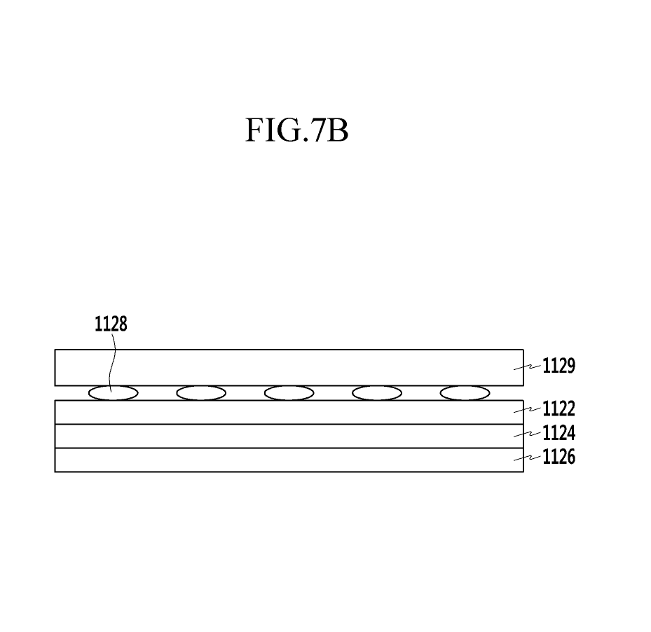

Referring to FIG. 7A, a passivation member 60 according to example embodiments includes a lower protection layer 62, wavelength conversion materials 64 doped in the lower protection layer 62, a micro-lens array 66 disposed on the lower protection layer 62, and an upper protection layer 68 disposed on the micro lens array 66.

The micro-lens array 66 may collect light beams heading for the lower protection layer 62 to collect photons, thereby increasing the wavelength conversion efficiency of the wavelength conversion materials 64.

The upper protection layer 68 may limit (and/or prevent) the direct contact between the micro-lens array 66 and the photoelectric layer (110 in FIG. 1) and may be omitted.

The wavelength conversion materials 64 contained in the lower protection layer 62 may be disposed at an upper portion of the lower protection layer 62 unlike the passivation members shown in FIGS. 3 to 5. Then, the wavelength conversion materials 64 become closer to the micro-lens array 66, and thus the light focused by the micro-lens array 66 may be directly absorbed by the wavelength conversion materials 64 but not by the lower protection layer 62.

The micro-lens array 66 and the upper protection layer 68 may be applied to the passivation members 10, 20, 30, 40 and 50 shown in FIGS. 2 to 6. However, when the micro-lens array 66 and the upper protection layer 68 are applied to FIGS. 3 to 5, the wavelength conversion materials 24, 34, 44 and 46 may be disposed on the protection layers 22, 32 and 42 but not thereunder. When the micro-lens array 66 and the upper protection layer 68 are applied to FIG. 6, the number of protection layers may be three.

Referring to FIG. 7B, a passivation member 1120 according to example embodiments may include a lower protection layer 1126, a wavelength conversion layer 1124, an intermediate protection layer 1122, a micro-lens array 1128, and an upper protection layer 1129 that are deposited in sequence. Each of the protection layers 1122, 1126 and 1129 may include protection material, but not wavelength conversion materials. The protection material in layers 1122, 1126, and 1129 may be the same or different.

As described above, when wavelength conversion materials are included in the passivation member 120 for protecting the photoelectric member 110 by using semiconductor processes, the efficiency of the solar cell 100 may be improved without high cost increase. A concentrating solar cell may exhibit more improved efficiency since the light intensity incident on the solar cell is concentrated.

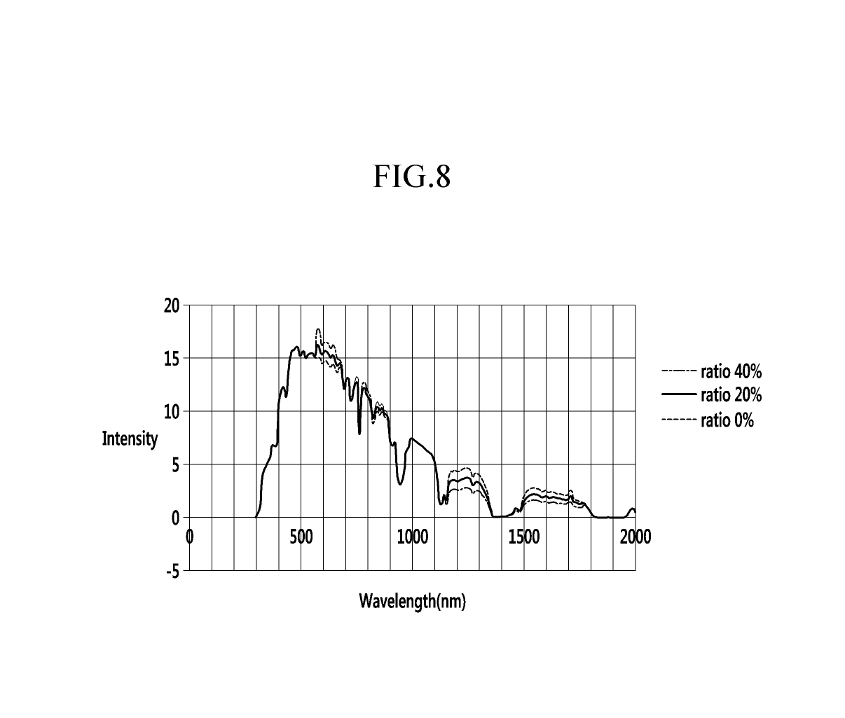

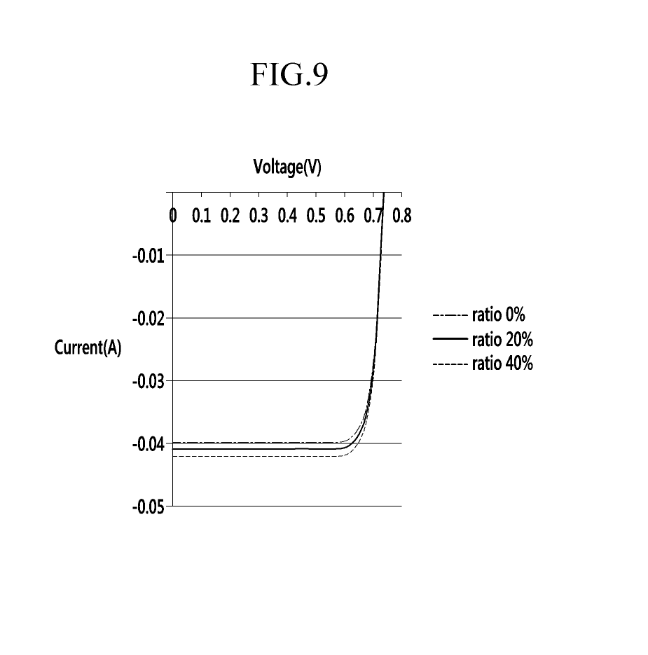

Next, characteristics of solar cells including passivation members with wavelength conversion materials are described in detail with reference to FIGS. 8 and 9.

FIG. 8 is a graph showing light spectrums for various wavelength conversion ratios, and FIG. 9 is a graph showing current-voltage (I-V) curves for various wavelength conversion ratios.

FIG. 8 shows light spectrums for solar cells including passivation members with wavelength conversion ratios of about 20% and about 40% respectively. Referring to FIG. 8, the solar cells with wavelength conversion ratios of about 20% and about 40% include passivation members with wavelength conversion material and are configured to convert about 20% and about 40% of incident light having a wavelength range of about 1,100 nm to about 1,700 nm wavelength range into light having a wavelength range of about 550 nm to about 850 nm. FIG. 8 further shows a light spectrum for a comparative solar cell including a passivation member without wavelength conversion material, as indicated by the ratio 0% label. It may be seen in FIG. 8 that the intensity of the light with wavelength of about 1,100 nm to about 1,700 nm decreases and the intensity of the light with wavelength of about 550 nm to about 850 nm increases, as the wavelength conversion ratio increases.

FIG. 9 shows I-V curves for solar cells with the wavelength conversion ratios of about 0%, about 20%, and about 40%. The short-circuit current density JSC, the open-circuit voltage V_{oc}, the fill factor FF, and the efficiency Eff of the solar cells were simulated and shown in Table 1.

TABLE 1

| Wavelength | | | | | |
|---|---|---|---|---|---|
| Conversion | Jsc | | | | Increment of |
| ratio | (mA/cm²) | Voc (mV) | FF (%) | Eff (%) | Efficiency |
| 0% | 39.7 | 735 | 83 | 24.3 | 0 |
| 20% | 40.9 | 736 | 83 | 25.1 | 0.8% |
| 40% | 42.2 | 737 | 83 | 25.9 | 1.6% |

Referring to Table 1 and FIG. 9, the short-circuit current density J_{sc} and the efficiency Eff of the solar cell with the wavelength conversion ratio of about 20% were increased by about 1.2 (mA/cm2) and about 0.8%, respectively, compared with the solar cell with the wavelength conversion ratio of about 0%. The solar cell with the wavelength conversion ratio of about 40% showed increased efficiency by about 1.6% compared with the solar cell with the wavelength conversion ratio of about 0%.

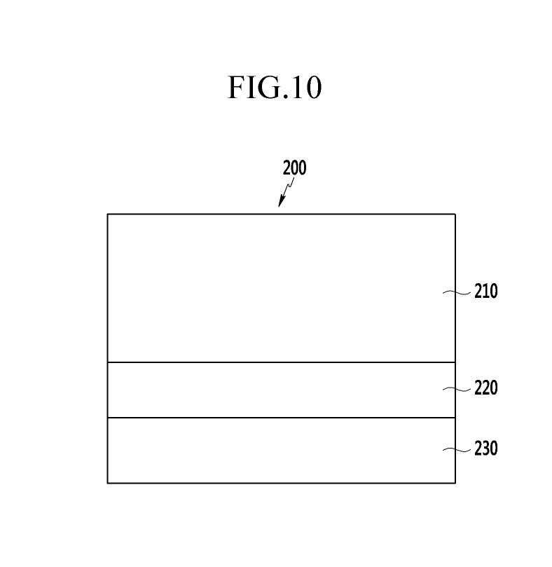

Next, a solar cell according to example embodiments is described in detail with reference to FIG. 10.

FIG. 10 is a schematic sectional view of a solar cell according to example embodiments.

A solar cell 200 according to example embodiments includes a photoelectric member 210, a passivation member 220 disposed under the photoelectric member 210, and a reflection member 230 disposed under the passivation member 220.

The passivation member 220 example embodiments includes both a protection material and a wavelength conversion material, and may have a structure shown in one of FIGS. 2 to 6, 7A and 7B.

The reflection member 230 may include a reflective material, for example, a metal, and may reflect light toward the photoelectric member 210. The light reflected by the reflection member 230 may include one that passes through the photoelectric member 210 and the passivation member 220 but not being absorbed by the photoelectric member 210 and the passivation member 220. Another light reflected by the reflection member 230 may be one emitted from the wavelength conversion material of the passivation member 220. The reflection member 230 may improve the power generation efficiency of the solar cell 200. The reflection member 230 may be connected to the photoelectric member 210 to serve as an electrode.

When the solar cell 200 includes the metallic reflection member 230 as shown in FIG. 10, and when the reflection member 230 serves as an electrode, the wavelength conversion material in the passivation member 220 may be surrounded by the protection material, for example, surrounded by the two protection layers 52 and 58 as described above with reference to FIG. 6.

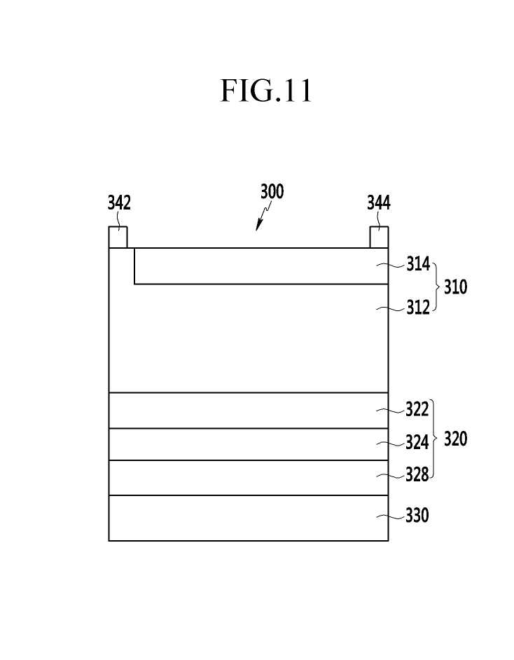

Now, solar cells according to example embodiments are described in detail with reference to FIGS. 11 to 20, and 21(a) to 21(b).

FIGS. 11 to 20, and 21(a) to 21(b) are schematic sectional views of solar cells according to example embodiments.

Referring to FIG. 11, a solar cell 300 according to example embodiments includes a photoelectric member 310, a passivation member 320, a reflection member 330, an active electrode 342, and an emitter electrode 344.

The photoelectric member 310 may include a junction of an active layer 312 and an emitter 314 that have opposite conductivities. For example, the active layer 312 may be a P-type single crystalline silicon substrate, and the emitter 314 may be formed by implanting N-type impurity into the substrate. Alternatively, the active layer 312 may be an N-type single crystalline silicon substrate, and the emitter 314 may be formed by implanting P-type impurity into the substrate. However, example embodiments are not limited thereto. For example, one having ordinary skill in the art would appreciate that the photoelectric member 310 may contain an elemental semiconductor other than crystalline silicon, a compound semiconductor, or an organic semiconductor.

The two electrodes 342 and 344 are connected to the photoelectric member 310. The active electrode 342 is connected to the active layer 312, and the emitter electrode 344 is connected to the emitter 314.

The passivation member 320 includes an upper protection layer 322, a wavelength conversion layer 324, and a lower protection layer 328. The passivation member 320 may include the passivation member 50 illustrated in FIG. 6.

Another protection layer (not shown) or an anti-reflection layer (not shown) may be disposed on an exposed surface of the emitter 314, and unevenness may be formed on a surface of the solar cell 300 for increasing light incident efficiency.

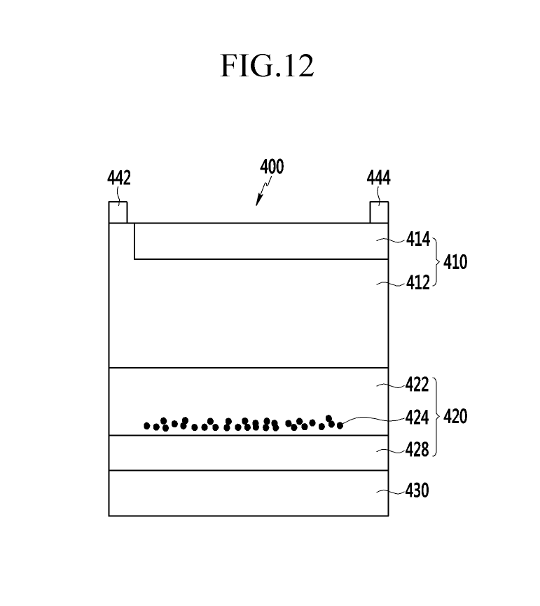

Referring to FIG. 12, a solar cell 400 according to example embodiments includes a photoelectric member 410, a passivation member 420, a reflection member 430, an active electrode 442, and an emitter electrode 444 like the solar cell 300 shown in FIG. 11. In addition, the photoelectric member 410 includes an active layer 412 and an emitter 414.

However, unlike the solar cell 300 shown in FIG. 11, the passivation member 420 of the solar cell 400 according to example embodiments includes an upper protection layer 422, wavelength conversion materials 424 disposed in the upper protection layer 422, and a lower protection layer 428. The wavelength conversion materials 424 may include ion-type wavelength conversion materials or quantum dots. Alternatively, the wavelength conversion materials 424 may include a combination of ion-type wavelength conversion materials and quantum dots.

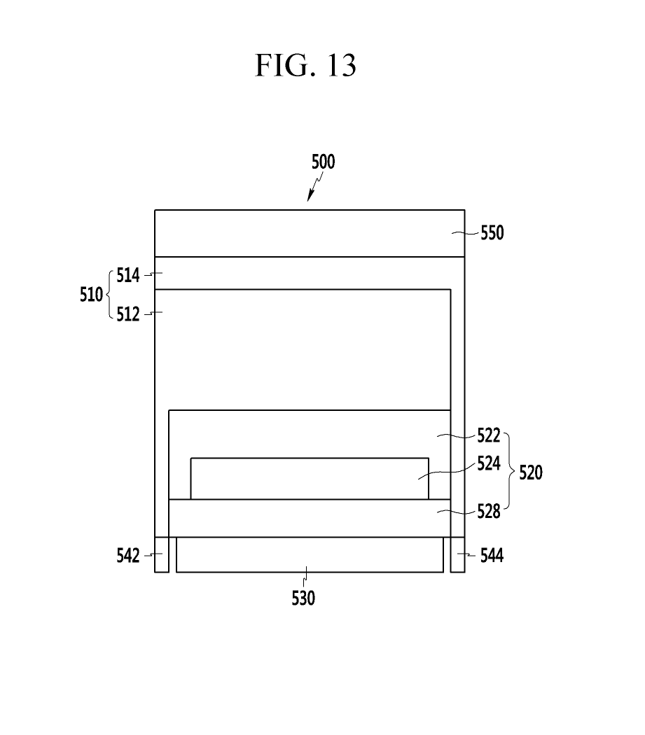

Referring to FIG. 13, a solar cell 500 according to example embodiments includes a photoelectric member 510, a passivation member 520, a reflection member 530, an active electrode 542, and an emitter electrode 544 like the solar cell 300 shown in FIG. 11. In addition, the photoelectric member 510 includes an active layer 512 and an emitter 514, and the passivation member 520 includes an upper protection layer 522, a wavelength conversion layer 524, and a lower protection layer 528.

However, unlike the solar cell 300 shown in FIG. 11, in the solar cell 500 according to example embodiments, the electrodes 542 and 544 are disposed at lower portions of the solar cell 500, and the upper protection layer 522 surrounds the wavelength conversion layer 524 so that the electrodes 542 and 544, the active layer 512 or the emitter 514 may not be in contact with the wavelength conversion layer 524. Furthermore, the solar cell 500 according to example embodiments may further include a front protection layer 550 to protect an exposed surface of the emitter 514, and the front protection layer 550 may serve as an anti-reflection layer.

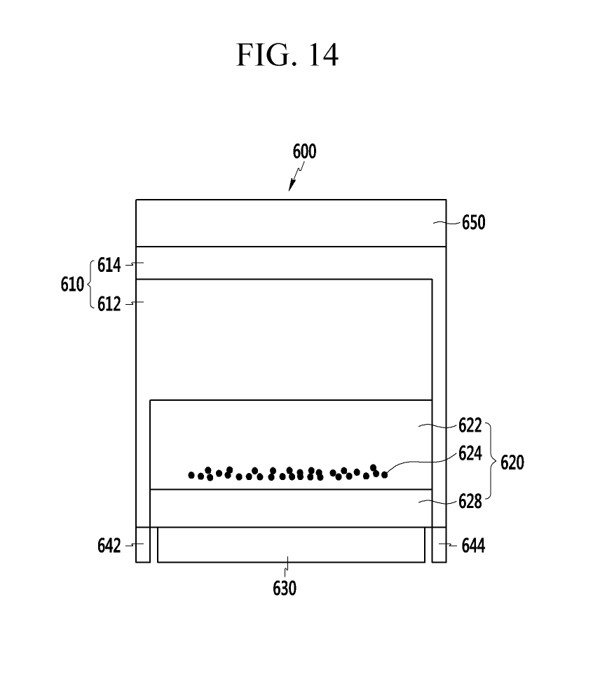

Referring to FIG. 14, a solar cell 600 according to example embodiments includes a photoelectric member 610, a passivation member 620, a reflection member 630, an active electrode 642, an emitter electrode 644, and a front protection layer 650 like the solar cell 500 shown in FIG. 13. In addition, the photoelectric member 610 includes an active layer 612 and an emitter 614.

However, unlike the solar cell 500 shown in FIG. 13, the passivation member 620 of the solar cell 400 according to example embodiments includes an upper protection layer 622, wavelength conversion materials 624 disposed in the upper protection layer 622, and a lower protection layer 628. The wavelength conversion materials 624 may include ion-type wavelength conversion materials or quantum dots. Alternatively, the wavelength conversion materials 624 may include a combination of ion-type wavelength conversion materials and quantum dots.

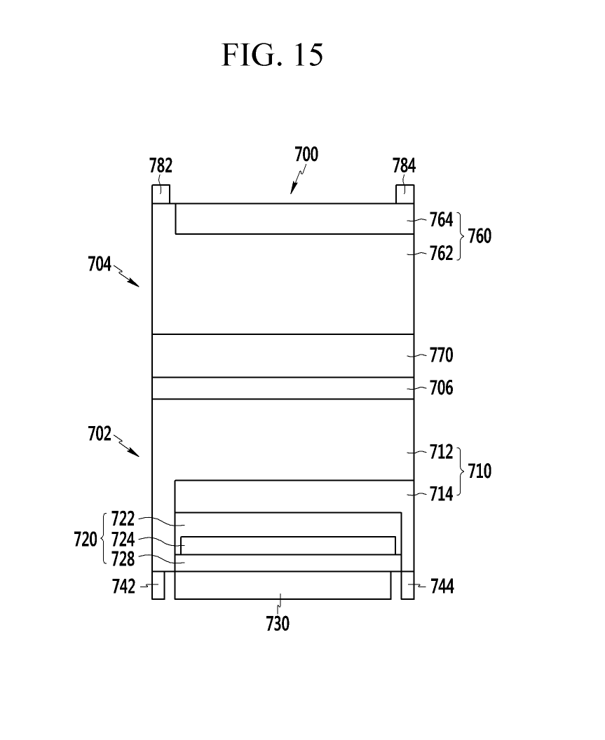

Referring to FIG. 15, a solar cell 700 according to example embodiments is a stacked solar cell, and includes a lower unit 702, an upper unit 704, and an insulating layer 706 disposed between the lower unit 702 and the upper unit 704.

The lower unit 702 includes a photoelectric member 710, a passivation member 720, a reflection member 730, an active electrode 742, and an emitter electrode 744, like the solar cell 500 shown in FIG. 13. In addition, the photoelectric member 710 includes an active layer 712 and an emitter 714, and the passivation member 720 includes an upper protection layer 722, a wavelength conversion layer 724, and a lower protection layer 728. However, unlike the solar cell 500 shown in FIG. 13, the lower unit 702 according to example embodiments does not include and a front protection layer, and the insulating layer 706 may serve as the front protection layer.

The upper unit 704 includes a photoelectric member 760, a protection layer 770, an active electrode 782, and an emitter electrode 784, and the photoelectric member 760 includes an active layer 762 and an emitter 764. The protection layer 770 of the upper unit 704 may include only a protection material but not wavelength conversion materials.

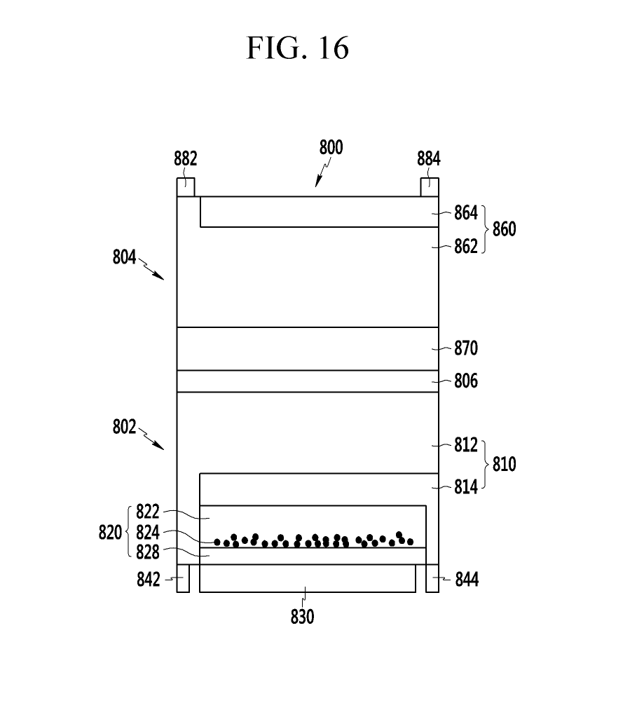

Referring to FIG. 16, a solar cell 800 according to example embodiments includes a lower unit 802, an upper unit 804, and an insulating layer 806 disposed between the lower unit 702 and the upper unit 704 like the solar cell 700 shown in FIG. 15. In addition, the upper unit 804 includes a photoelectric member 860, a protection layer 870, an active electrode 882, and an emitter electrode 884, and the photoelectric member 860 includes an active layer 862 and an emitter 864. The lower unit 802 includes a photoelectric member 810, a passivation member 820, a reflection member 830, an active electrode 842, and an emitter electrode 844, and the photoelectric member 810 includes an active layer 812 and an emitter 814.

However, unlike the solar cell 700 shown in FIG. 15, the passivation member 820 of the lower unit 802 of the solar cell 800 according to example embodiments includes an upper protection layer 822, wavelength conversion materials 824 disposed in the upper protection layer 822, and a lower protection layer 828. The wavelength conversion materials 824 may include ion-type wavelength conversion materials or quantum dots. Alternatively, the wavelength conversion materials 824 may include a combination of ion-type wavelength conversion materials and quantum dots.

Passivation members according to example embodiments may be applied to a solar cell including three or more stacked units.

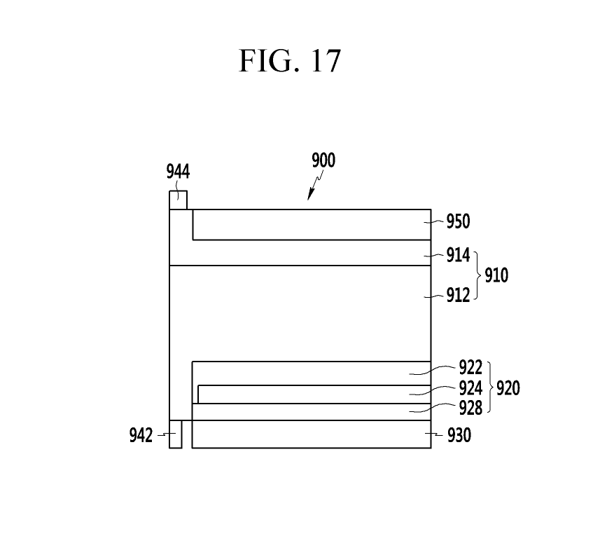

Referring to FIG. 17, a solar cell 900 according to example embodiments includes a photoelectric member 910, a passivation member 920, a reflection member 930, an active electrode 942, and an emitter electrode 944 like the solar cell 300 shown in FIG. 11. In addition, the photoelectric member 910 includes an active layer 912 and an emitter 914, and the passivation member 920 includes an upper protection layer 922, a wavelength conversion layer 924, and a lower protection layer 928.

However, unlike the solar cell 300 shown in FIG. 11, in the solar cell 900 according to example embodiments, the emitter electrode 944 is disposed at a top of the solar cell 900, while the active electrode 942 is disposed at a bottom of the solar cell 900. The upper protection layer 922 surrounds the wavelength conversion layer 924 so that the active electrode 942 and the active layer 912 may not be in contact with the wavelength conversion layer 924.

Furthermore, the solar cell 900 may further include a front protection layer 950 to protect an exposed surface of the emitter 914, and the front protection layer 950 may serve as an anti-reflection layer.

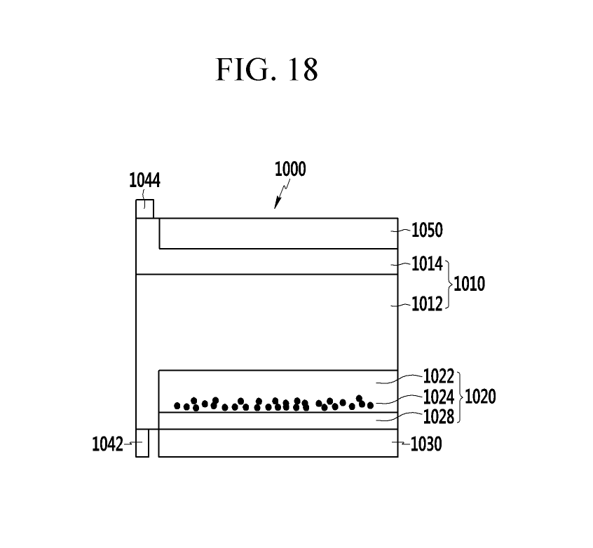

Referring to FIG. 18, a solar cell 1000 according to example embodiments includes a photoelectric member 1010, a passivation member 1020, a reflection member 1030, an active electrode 1042, and an emitter electrode 1044 like the solar cell 900 shown in FIG. 17. In addition, the photoelectric member 1010 includes an active layer 1012 and an emitter 1014.

However, unlike the solar cell 900 shown in FIG. 17, the passivation member 1020 of the lower unit 1002 of the solar cell 1000 according to example embodiments includes an upper protection layer 1022, wavelength conversion materials 1024 disposed in the upper protection layer 1022, and a lower protection layer 1028. The wavelength conversion materials 1024 may include ion-type wavelength conversion materials or quantum dots. Alternatively, the wavelength conversion materials 1024 may include a combination of ion-type wavelength conversion materials and quantum dots.

Furthermore, the solar cell 1000 may further include a front protection layer 1050 to protect an exposed surface of the emitter 1014, and the front protection layer 1050 may serve as an anti-reflection layer.

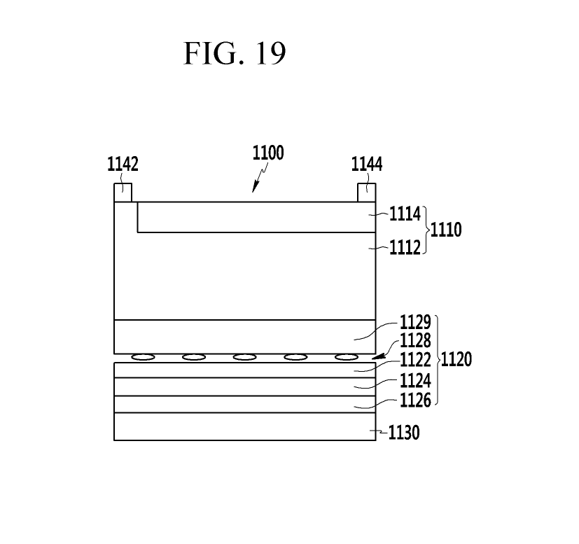

Referring to FIG. 19, a solar cell 1100 according to example embodiments includes a photoelectric member 1110, a passivation member 1120, a reflection member 1130, an active electrode 1142, and an emitter electrode 1144 like the solar cell 300 shown in FIG. 11. In addition, the photoelectric member 1110 includes an active layer 1112 and an emitter 1114.

However, unlike the solar cell 300 shown in FIG. 11, the passivation member 1120 of the solar cell 1100 includes a lower protection layer 1126, a wavelength conversion layer 1124, an intermediate protection layer 1122, a micro-lens array 1128, and an upper protection layer 1129 that are deposited in sequence. Each of the protection layers 1122, 1126 and 1129 may include a protection material, but not wavelength conversion material. The wavelength conversion layer 1124 may include wavelength conversion material.

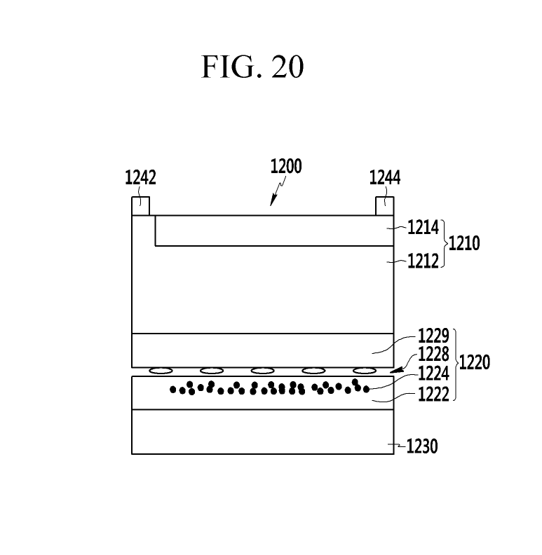

Referring to FIG. 20, a solar cell 1200 according to example embodiments includes a photoelectric member 1210, a passivation member 1220, a reflection member 1230, an active electrode 1242, and an emitter electrode 1244 like the solar cell 1100 shown in FIG. 19. In addition, the photoelectric member 1210 includes an active layer 1212 and an emitter 1214.

However, unlike the solar cell 1100 shown in FIG. 19, the passivation member 1220 of the solar cell 1200 according to example embodiments includes a lower protection layer 1222, wavelength conversion materials 1224 disposed in the lower protection layer 1222, a micro-lens array 1228, and an upper protection layer 1229. The wavelength conversion materials 1224 may be disposed on the lower protection layer 1222 and may include ion-type wavelength conversion materials or quantum dots. Alternatively, the wavelength conversion materials 1224 may include a combination of ion-type wavelength conversion materials and quantum dots.

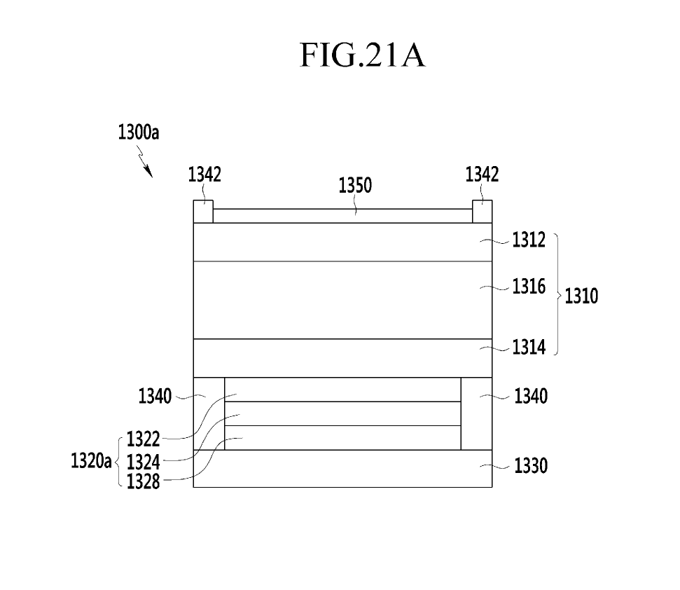

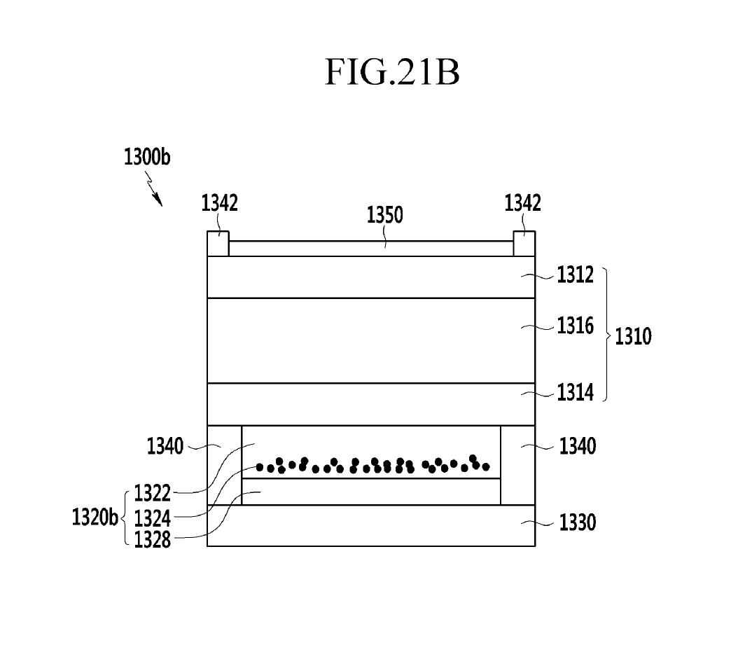

Referring to FIG. 21(a), according to example embodiments, a solar cell 1300a includes a photoelectric member 1310, a passivation member 1320a, and a transparent electrode pattern 1340 on a reflection member 1330. The photoelectric member 1310 includes a p-i-n junction defined by a first conductivity-type layer 1312, intrinsic layer 1316, and a second conductivity-type layer 1314 sequentially stacked. The first conductivity-type layer 1312 includes one of an N-type and a P-type impurity. The second conductivity-type layer 1314 includes the other of the N-type and the P-type impurity. Materials for the photoelectric member 1310 include, for example, one of an elemental semiconductor, a compound semiconductor, and an organic semiconductor. The photoelectric member 1310 may include amorphous or crystalline silicon, but example embodiments are not limited thereto. The solar cell 1300a may further include at least one electrode 1342 on the first conductivity-type layer 1312 containing a metal or transparent conductive material, and a front protection layer 1350 containing a dielectric material; however, example embodiments are not limited thereto. The front protection layer 1350 may function as an anti-reflective layer.

The transparent electrode pattern 1340 may provide an electrical connection between the second conductivity-type layer 1314 and the reflection member 1330. The reflection member 1330 may function as an electrode. The reflection member 1330 may include a reflective material, for example, a metal, and may reflect light toward the photoelectric member 1310. The transparent electrode pattern may include a transparent conductive oxide including at least one of zinc oxide, indium oxide, tin oxide, indium tin oxide, and combinations thereof. However, example embodiments are not limited thereto.

The passivation member 1320a includes an upper protection layer 1322, a wavelength conversion layer 324, and a lower protection layer 328. The passivation member 1320a may include the passivation member 50 illustrated in FIG. 6. Alternatively, the passivation member 1320a may be formed like the passivation member 720 illustrated in FIG. 15, discussed above, where the upper protection layer 722 surrounds a top surface and side surfaces of the wavelength conversion layer 724.

Referring to FIG. 21(b), the solar cell 1300b is similar to the solar cell 1300a shown in FIG. 21(a), except that the passivation member 1320b of the solar cell in FIG. 21(b) includes a different structure than the passivation member 1320a of the solar cell in FIG. 21(a).

Unlike the passivation member 1320a in FIG. 21(a), the passivation member 1320b of the solar cell 1300b includes an upper protection layer 1322, wavelength conversion materials 1324 disposed in the upper protection layer 1322, and a lower protection layer 1328. The wavelength conversion materials 1324 may include ion-type wavelength conversion materials or quantum dots. Alternatively, the wavelength conversion materials 1324 may include a combination of ion-type wavelength conversion materials and quantum dots.

Although FIGS. 10 to 20, and 21(a) to 21(b) illustrate schematic sectional views of solar cells according to example embodiments, example embodiments are not limited thereto. One having ordinary skill in the art would appreciate that one or more of the foregoing solar cells according to example embodiments may be electrically connected in series, parallel, and series-parallel arrangements in order to form a solar cell module configured to generate desired current, voltage, and/or power characteristics.

While some example embodiments have been particularly shown and described, it will be understood by one of ordinary skill in the art that variations in form and detail may be made therein without departing from the spirit and scope of the claims.

What is claimed is:

1. A solar cell comprising:
a photoelectric member on a passivation member,
the photoelectric member configured to convert light into current,
the passivation member including,
protection material for protecting the photoelectric member, and
wavelength conversion material configured to convert light that passes through the photoelectric member into a different wavelength.

2. The solar cell of claim 1, wherein the wavelength conversion material comprises at least one of a rare earth ion, a transition metal ion, and a quantum dot.

3. The solar cell of claim 2, wherein the protection material comprises at least one of silicon oxide, silicon nitride, and aluminum oxide.

4. The solar cell of claim 3, wherein
the photoelectric member comprises single crystalline silicon, and
the wavelength conversion material is configured to convert light having a wavelength of about 1,100 nm to about 1,700 nm into light having a wavelength of about 550 nm to about 850 nm.

5. The solar cell of claim 4, wherein
the passivation member comprises a first protection layer,
the first protection layer comprises the protection material, and
the wavelength conversion material is in the first protection layer.

6. The solar cell of claim 5, wherein the wavelength conversion material comprises at least one of a rare earth ion and a transition metal ion.

7. The solar cell of claim 5, wherein
the protection material comprises at least one of silicon oxide and silicon nitride, the wavelength conversion material comprises a quantum dot, and
the quantum dot is a Si nanocrystal.

8. The solar cell of claim 5, wherein
the wavelength conversion material comprises the quantum dot and at least one of the rare earth ion and the transition metal ion, and
the quantum dot is a Si nanocrystal.

9. The solar cell of claim 5, wherein the passivation member further comprises a micro-lens array on the first protection layer.

10. The solar cell of claim 9, wherein
the wavelength conversion material in the first protection layer is near a first surface of the first protection layer, and
the first surface of the first protection layer is closer to the micro-lens array than a second surface of the first protection layer opposite the first surface.

11. The solar cell of claim 9, wherein the passivation member further comprises a second protection layer on the micro-lens array.

12. The solar cell of claim 4, wherein the passivation member comprises:
a first protection layer comprising the protection material; and
a wavelength conversion layer under the first protection layer,
the wavelength conversion layer comprising the wavelength conversion material.

13. The solar cell of claim 12, wherein
the passivation member further comprises a second protection layer under the wavelength conversion material, and
the second protection layer comprises the protection material.

14. The solar cell of claim 12, further comprising:
a reflection member under the wavelength conversion material.

15. The solar cell of claim 14, wherein
the protection material surrounds the wavelength conversion material such that the wavelength conversion material is spaced apart from the reflection member and does not contact the reflection member.

16. The solar cell of claim 12, wherein
the photoelectric member comprises a junction of an active layer and an emitter, and
the active layer and the emitter have opposite conductivities.

17. The solar cell of claim 16, wherein
the emitter is farther from the passivation member than the active layer, and
the solar cell further comprises a second protection layer configured to protect a surface of the emitter.

18. The solar cell of claim 16, further comprising:
a first electrode connected to the active layer; and
a second electrode connected to the emitter,
wherein the first and second electrodes are on one side or opposite sides of the solar cell.

19. The solar cell of claim 16, wherein the photoelectric member comprises at least two units separated by an insulating layer.

20. The solar cell of claim 12, wherein the passivation member further comprises a micro-lens array between the photoelectric member and the wavelength conversion layer.

21. The solar cell of claim 20, wherein the passivation member further comprises a second protection layer on the micro-lens array.

22. The solar cell of claim 12, wherein
the passivation member further comprises a second protection layer under the wavelength conversion material, and
the first and second protection layers include different materials.

23. The solar cell of claim 1, wherein the photoelectric member includes a p-i-n junction.

24. The solar cell of claim 23, further comprising:
a transparent conductive oxide pattern surrounding the passivation member, wherein the transparent conductive oxide pattern connects the photoelectric member to the reflecting member.

25. The solar cell of claim 1, wherein the photoelectric member includes at least one of an elemental semiconductor, a compound semiconductor, and an organic semiconductor.
